(19) United States
(12) Patent Application Publication
(10) Pub. No.: US 2025/0208197 A1
(43) Pub. Date: Jun. 26, 2025

(54) MULTI ZONE TEMPERATURE CONTROL FOR DEVICES UNDER TEST

(71) Applicant: INTEL CORPORATION, Santa Clara, CA (US)

(72) Inventors: Gregorio R. MURTAGIAN, Phoenix, AZ (US); Paul DIGLIO, Gaston, OR (US); Craig YOST, Gilbert, AZ (US); Sami ALELYANI, Phoenix, AZ (US)

(21) Appl. No.: 18/394,108

(22) Filed: Dec. 22, 2023

(51) Int. Cl. G01R 31/28

(52) U.S. Cl. CPC G01R 31/2875; G01R 31/2877

(57) ABSTRACT

Provided is a fluid delivery system with a plurality of nozzles to control the temperatures of multiple zones in a device under test.

### TECHNICAL FIELD

Embodiments of the invention relate to the field of semiconductor testing apparatuses; and more specifically, to fluid delivery assemblies for controlling the temperature of a device under test.

### BRIEF DESCRIPTION OF THE DRAWINGS

The disclosure may best be understood by referring to the following description and accompanying drawings that are used to illustrate embodiments of the invention. In the drawings:

FIGS. 1A and 1B show a nozzle assembly for providing multizone temperature control of a device under test (DUT) 175 in accordance with some embodiments.

FIG. 2 is a diagram schematically illustrating a nozzle in accordance with some embodiments.

FIG. 3 is a diagram showing a testing apparatus with multizone fluid delivery temperature management in accordance with some embodiments.

FIG. 4 is a diagram illustrating another test apparatus configuration in accordance with some embodiments.

FIG. 5 is a diagram showing rectangularly shaped spray fields over a DUT in accordance with some embodiments.

### DETAILED DESCRIPTION

In order to properly test an integrated circuit (IC) device such as a die, a multi-chip die, or a die package (hereinafter collectively referred to as a device under test, DUT), die temperature control during back-end class testing is important for testing their performance. Devices can have one or multiple dies and typically have different power density areas that produce varying junction temperatures (Tj). Thus, it is desirable to be able to facilitate a multi zone temperature control to achieve local temperature control for different zones of a DUT.

Another issue is that in order to be able to effectively control temperature for the various zones of a DUT, efficient cooling systems are desired. With fluid cooling systems, a measure of efficiency is the vapor (e.g., water vapor) quality which is the mass ratio of vapor to liquid that exits a cooling system. A higher ratio is typically desired since this implies that more of the cooling fluid has been vaporized, removing more heat than if liquid fluid was simply heated without changing phase. An efficient system can reduce the equipment power and size requirements and also enables better temperature control in that temperature spikes can be more quickly redressed.

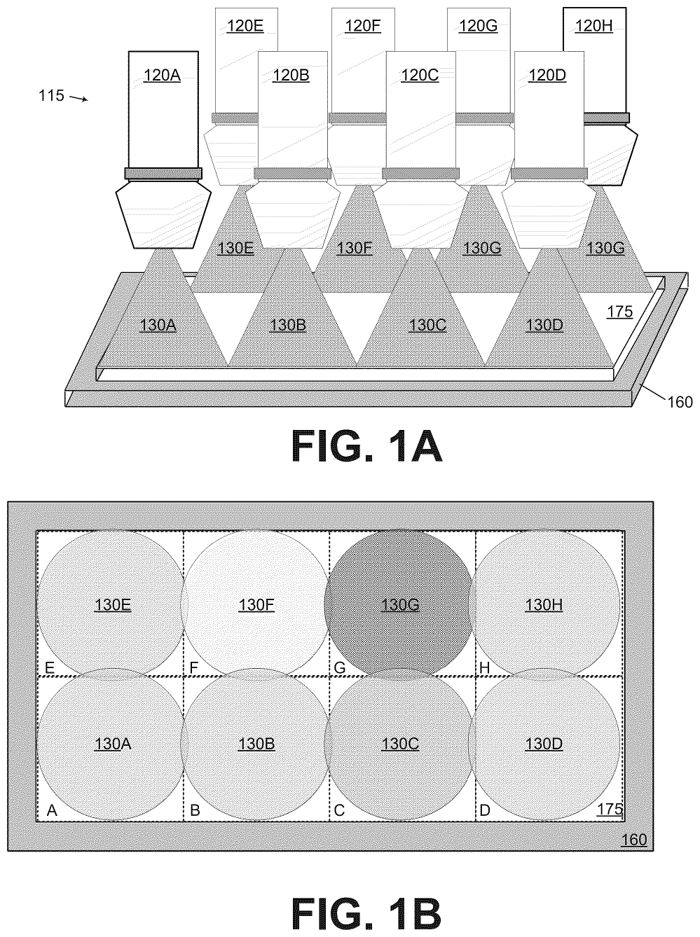

FIGS. 1A and 1B show a nozzle assembly 115 for providing multizone temperature control of a device under test (DUT) 175 in accordance with some embodiments. FIG. 1A is a perspective schematic view illustrating the assembly 115. In this example, the nozzles 120 are arranged in a rectangularly shaped 2×4 array group corresponding to the shape of the DUT 175 whose zone temperatures are to be controlled. Each nozzle 120 projects an independently controllable fluid spray field 130, which may include any suitable heat transfer fluid such as water for managing temperature. The fluid may primarily be used as a coolant but in some scenarios, it may also be used to heat one or more DUT zones, depending on the particular test being performed.

FIG. 1B is a top view illustrating the different incident surface regions (A-H) associated with the temperature zones of the DUT 175. Also shown are the corresponding spray coverage areas defined by the spray fields (130A-130H) that are projected onto the DUT surface regions (hereinafter referred simply to as regions) by the nozzles 120A-120H, respectively. Multi zone temperature control is obtained by dispensing the fluid through the nozzle assembly where each individual nozzle flow may be independently controlled. Different colors for the different spray fields (130A-130H) indicate different coolant flow parameters (e.g., flow rates) from the different individual nozzles.

An assembly, or group, of nozzles can comprise any number and shape of nozzles, depending, for example, on nozzle spray coverage area, DUT size/shape, desired power dissipation capabilities, and desired temperature control zone granularity. For example, with fluid delivery assembly 115, eight nozzles (120A-120H) are arranged to cover a rectangularly shaped DUT incident surface that has dimensions of 20 mM by 40 mM. At the desired distance for the nozzle heads to the incident DUT surface, the nozzles project circular incident spray fields having 10 mM diameters. Thus, a 2×4 array is used. Of course, the spray fields could be adjusted to completely cover the DUT surface, with overlapping spray field regions, depending on specific factors such as desired operational performance and the particular sizes and distribution of the DUT's hot spot areas. Along these lines, while the depicted zone regions (regions associated with DUT zones to be managed) are equivalent in size and shape, other embodiments may have regions with different sizes and/or shapes.

In some embodiments, the DUT may be connected to a test socket 160 that not only facilitates electrical test performance of the DUT, but also, may provide temperature information from the DUT itself in order to monitor temperatures in the zones to be controlled. Temperature sensors within the DUT itself may be used to monitor the different zones to be thermally managed. In this way, the nozzles may be individually controlled to move more or less heat away from a given zone, depending on a zone's sensed (or monitored) temperature and target control temperature.

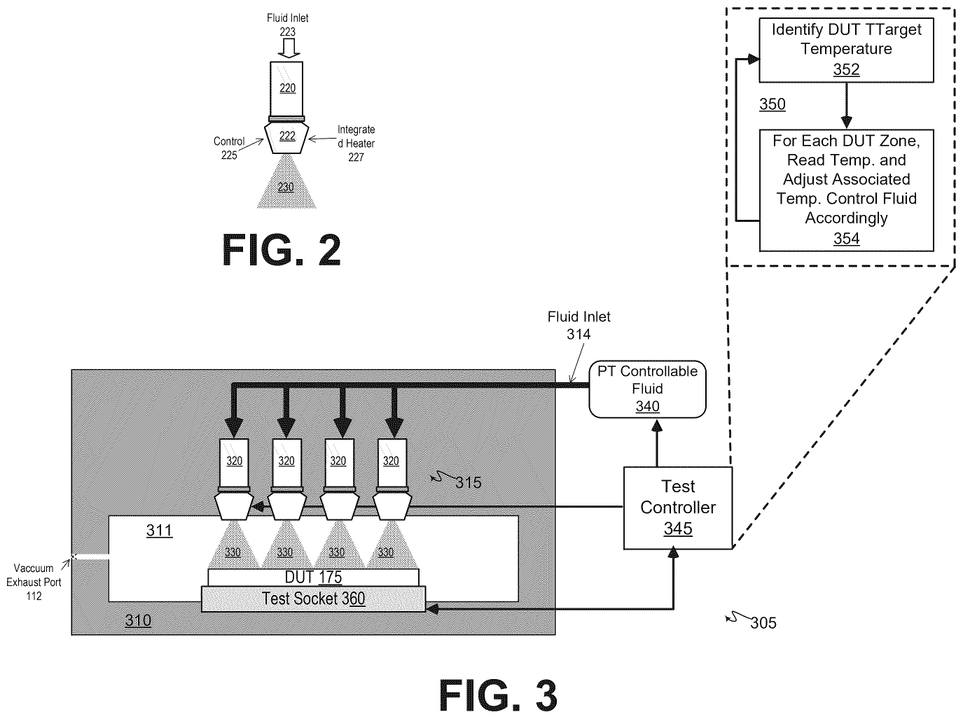

FIG. 2 is a diagram schematically illustrating a nozzle 220 in accordance with some embodiments. Nozzle 220 has a fluid inlet 223 and a nozzle head 222 with nozzle spray outlet 224. It also has a control interface 225 and an integrated heater 227 in this implementation. The fluid inlet 223 is capable of receiving a pressurized and heated supply of temperature controlling fluid such as water. The nozzle head 222 includes a valve and valve actuator (not shown) such as a solenoid or piezo-electrically controlled valve actuator for controlling the flow rate of the projected spray 230. In some embodiments, it may create an elliptical or circular spray coverage region, as is illustrated in FIG. 1B. In other embodiments, nozzles may be utilized that generate other shaped spray incident regions such as rectangular regions, as are shown in the diagram of FIG. 5.

The nozzle head 222 also includes suitable structure for generating uniformly sized fluid droplets that ideally exit the nozzle at a substantially uniform speed. Even though the supplied fluid may be heated, the head may also include a heater 227 to compensate for heat that may be lost by the fluid traveling between the inlet and the outlet.

The actuators can have very small sizes (e.g., <6 mM in diameter), which allows for microsecond level fluid control responsiveness for quick thermal reactivity. This may even be done without the need of increasing the chamber vapor saturation pressure with the use of an air stent. With water as a fluid, water quality and efficiency may be enhanced by optimizing the nozzle design by controlling the flow Weber number (the ratio of inertial forces to surface tension), which affects water atomization and heat transfer efficiency. (Note that any suitable fluid may be used for temperature management in a fluid delivery system. While water is an excellent thermal management fluid for many applications, other fluids, e.g., having lower or higher boiling points, may be used, depending on overall design considerations.)

In addition, it should be appreciated that any suitable nozzle design type may be employed. For example, hollow cone nozzles (e.g., axial or tangential flow) such as those offered from Lechler, Inc.™ may be used. Hollow cone spray nozzles can produce very small droplets and may have structures such as inserts with spiral grooves to generate efficient rotation of the fluid, which helps to create uniform droplets. In addition, some may also use pulse-width-modulated valves for generating precise minimum quantity atomization, uniformly sprayed on specific die areas with an average droplet velocity allowing for efficient heat transfer.

FIG. 3 is a diagram showing a testing apparatus with multizone fluid delivery temperature management in accordance with some embodiments. The test apparatus 305 generally includes a chassis (or housing) 310 with a fluid inlet 314 and a pressure and temperature controllable chamber 311 including a vacuum exhaust port 112 for evacuating liquid, as well as gasses such as air to maintain a suitable vacuum environment. The chassis 310 also includes a fluid delivery assembly 315 and a test socket 360 for receiving a device under test (DUT) 175 for operational testing under temperature regulated conditions. The fluid delivery assembly 315 has nozzles 320 to apply independently controllable spray fluid fields 330 onto the DUT 175.

The test apparatus 305 also has a pressurizable and temperature controlled fluid supply 340 and a test controller 345 coupled as shown. The fluid supply 340 is fluidly coupled to the fluid inlet 314 to provide to the fluid delivery assembly 315 suitable fluid such as heated and/or pressurized water for single phase, two phase, or a combination of both single and two phase cooling.

(Note that two-phase change properties of fluids can be used to enable high density cooling. In some scenarios, the working fluid may be put under a controlled vacuum to regulate the amount of cooling power possible. In addition, the working fluid may be preheated to near or slightly above the intended target temperature of the DUT, further reducing the amount of time needed for the fluid to boil on the surface. (For example, given vacuum conditions where water will boil at 80 degrees C., the water provided to nozzles 320 may be heated to a temperature in a range between 79 and 81 degrees C.) Thus, heat transfer performance can be more flexibly controlled by controlling fluid conditions including fluid flow, incoming fluid temperature and fluid environment pressure, in addition to other optimization details to maximize surface area of the heat-exchange area on both the DUT and working fluid. In some two-phase cooling embodiments, the fluid may be heated to a few degrees below the intended DUT target temperature (boiling point of the fluid at a specific vacuum level), and the fluid is sprayed onto the die using, for example, a minimal flow-rate necessary to prevent dry-out. It should also be appreciated that while the use of heated fluids has primarily been discussed, unheated or cooled fluids could also be used. Likewise, the use of fluids for cooling DUT zones has primarily been addressed but in some embodiments, heated fluids could also be used for heating DUT zones, which may be desired in some testing scenarios.)

The test controller (e.g., comprising a microcontroller and/or processing system with a user interface) is electrically coupled with the fluid delivery assembly 315 and test socket 360 in a closed loop to control the nozzles 320 based on feedback zone temperatures received from the test socket 360. It has logic such as executable code (firmware, configurable application code, etc.) for implementing a DUT multizone temperature management process 350 in accordance with some embodiments.

Process 350 includes identifying target temperatures for the various DUT zone, or zones (352) and adjusting, or maintaining fluid flow for each zone based on zone temperature data (354), which may be received from the test connector 360. (Note that the test controller 350 may encompass a test management controller used with the test socket 360 for electrically testing DUT operational performance, or it may interface with a separate test control system otherwise used for this purpose.) IN some embodiments, the overall DUT may have a desired temperature range (e.g., 100 degrees C. to 110 degrees C.) for conducting operational performance testing of the DUT. To achieve this, the separate zones may be separately controlled to be at separate temperatures, all within the desired range. In other scenarios, the process may use an average of the constituent zone temperatures as a target. Regardless, it can monitor the individual zones and adjust an associated nozzle fluid flow characteristic accordingly. For example, in order to increase or decrease a zone's cooling rate, its associated nozzle's flow rate could be increased or decreased, respectively. In some embodiments, nozzle fluid temperatures and pressures may also be adjusted, for example, taking into account the chamber pressure in order to attain efficient two-phase cooling performance. In some embodiments, the test controller may control each nozzle by increasing its cooling rate (e.g., increase its flow rate) if the sensed temperature for its associated zone is above one or more upper target thresholds, and it may decrease its cooling rate, or even transition into a heating mode, if its sensed temperature is below one or more different lower target thresholds. (Multiple upper and lower target thresholds may be used, for example, to incorporate hysteresis in the control process and/or to apply non-linear cooling/heating, depending on how close a sensed temperature is to its desired range boundary.)

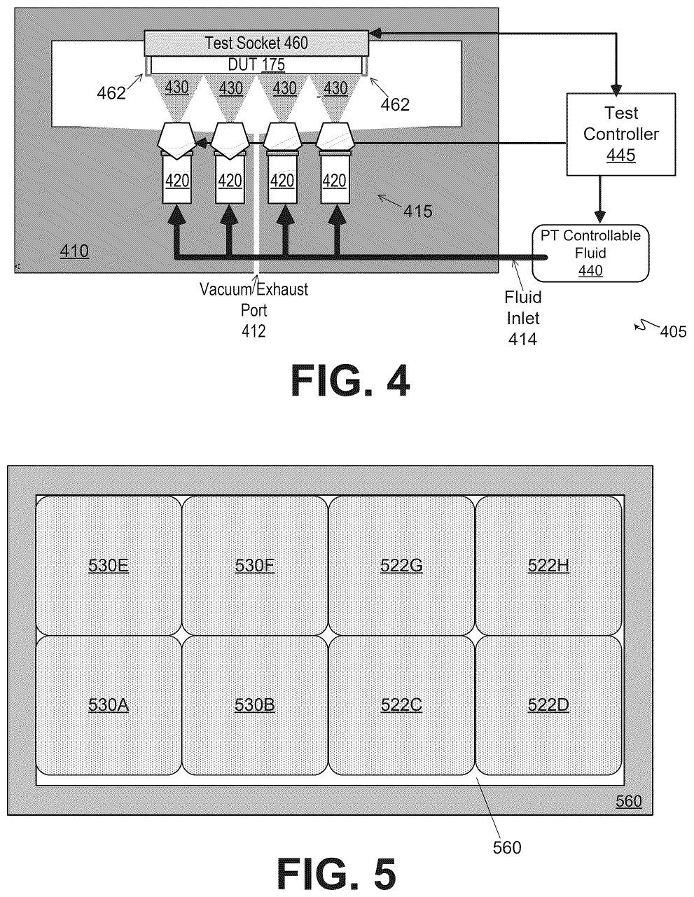

FIG. 4 is a diagram illustrating another test apparatus configuration in accordance with some embodiments. As with the test apparatus of FIG. 3, it includes a housing 410 with a fluid inlet 414 and a vacuum exhaust outlet port (outlet) 412 to draw gas and fluid out of the test chamber 411. However, with this embodiment, the housing 410 is vertically inverted, with its fluid delivery assembly 415 positioned at a lower end of the housing, directing fluid upward against the DUT and in opposition to a dominant gravitational force (i.e., Earth's gravity). Likewise, the test socket 460 is mounted at an upper end of the housing, directing the DUT, when connected therewith, downward facing the group of nozzles in the fluid delivery assembly 415. Releasable clips 462 are included with the test socket 460 to more securely hold the DUT 175 in place, which now hangs down from the socket 460.

With the depicted embodiment, the lower surface of the chamber 411, defined by housing 410, is slanted downward from its lateral sides, converging at a low portion (e.g., low-line, or low-point) at or near the middle of the chamber. The exhaust port is coupled to the chamber at this low portion of the chamber. While it is desirable for all of the fluid that is projected out of the nozzles to be vaporized, this is not always attainable. Accordingly, system should be able to adequately remove liquid and vapor that has already contacted the DUT, away from the DUT zone surfaces for them to be efficiently cooled by oncoming nozzle spray. With the upwardly projected spray, and downwardly slanted lower chamber surface (or “floor”) and exhaust port coupled to a bottom thereof, post contact fluid and fluid vapor is more readily drawn out of the chamber, thereby improving fluid delivery heat transfer efficiency. Note that while a single exhaust port (412 or 312 from FIG. 3) is shown, chamber housings may have one or more additional exhaust ports, e.g., exclusively for evacuating gas to maintain an adequate vacuum environment. IF there is excessive water to be exited, the exhaust port 412 may not be sufficient, alone, to maintain a suitable vacuum within the chamber.

Illustrative examples of the technologies disclosed herein are provided below. An embodiment of the technologies may include any one or more, and any compatible combination of, the examples described below.

Example 1 is an apparatus that includes a group of fluid delivery nozzles and a test controller. The group of fluid delivery nozzles are each positioned to project a field of spray onto an associated zone of a device under test (DUT). Each zone has an associated DUT temperature. The test controller is coupled to the nozzles to individually control each nozzle based on the associated temperature of its associated zone.

Example 2 includes the subject matter of Example 1, and wherein the nozzles are hollow cone nozzles.

Example 3 includes the subject matter of any of Examples 1-2, and wherein the hollow cone nozzles have piezoelectric valve actuators to be controlled by the test controller.

Example 4 includes the subject matter of any of Examples 1-3, and wherein the group of nozzles are arranged in a rectangular shaped array.

Example 5 includes the subject matter of any of Examples 1-4, and comprising a fluid supply source capable of providing heated and pressurized fluid.

Example 6 includes the subject matter of any of Examples 1-5, and wherein the fluid is water.

Example 7 includes the subject matter of any of Examples 1-6, and wherein the test controller comprises a processor circuit and executable code that when executed causes the processor circuit to increase a flow rate for a nozzle when its associated zone has an associated DUT temperature that is higher than an upper target threshold and causes the flow rate to decrease if the associated DUT temperature is below a lower target threshold.

Example 8 includes the subject matter of any of Examples 1-7, and wherein the group of fluid delivery nozzles are positioned to project the spray upward against a net gravitational force.

Example 9 includes the subject matter of any of Examples 1-8, and comprising a chamber having a downward sloping lower surface to channel fluid into an exhaust port.

Example 10 includes the subject matter of any of Examples 1-9, and wherein the chamber has an additional exhaust port for maintaining a desired vacuum pressure in the chamber.

Example 11 includes the subject matter of any of Examples 1-10, and comprising a test connector coupled with the test controller to provide it with the associated zone temperatures for the DUT.

Example 12 is a testing apparatus that includes a housing, a fluid inlet port, and a test connector. The housing has a chamber and a fluid delivery assembly with a plurality of fluid delivery nozzles to control a temperature of a device under test (DUT) having multiple zones each with an associated temperature. The fluid input port is to supply water to the plurality of fluid delivery nozzles. The test connector is to receive the DUT and to provide the associated zone temperatures to a test controller. Each of the plurality of fluid delivery nozzles are individually controllable based on associated multiple zone temperatures.

Example 13 includes the subject matter of Example 12, and wherein the nozzles are hollow cone nozzles.

Example 14 includes the subject matter of any of Examples 12-13, and wherein the plurality of nozzles are arranged in a shape corresponding to the DUT.

Example 15 includes the subject matter of any of Examples 12-14, and comprising a fluid supply source coupled to the fluid inlet port and capable of providing heated and pressurized fluid.

Example 16 includes the subject matter of any of Examples 12-15, and comprising the test controller including a processor circuit and executable code that when executed causes the processor circuit to increase a flow rate for a selected one of the plurality of nozzles when an associated zone temperature is higher than an upper target threshold and causes the flow rate to decrease if the associated zone temperature is below a lower target threshold.

Example 17 includes the subject matter of any of Examples 12-16, and wherein the plurality of fluid delivery nozzles are positioned to project the spray upward against a net gravitational force.

Example 18 includes the subject matter of any of Examples 12-17, and comprising a chamber having a downward sloping lower surface to channel fluid into an exhaust port.

Example 19 includes the subject matter of any of Examples 12-18, and wherein the chamber has an additional exhaust port for maintaining a desired vacuum pressure in the chamber.

Example 20 is a method. The method includes monitoring a temperature in each of multiple zones of a device under test (DUT), using a plurality of nozzles to project fluid onto the DUT to control the monitored temperatures, and controlling a cooling rate of each of the plurality of nozzles based on the monitored temperatures.

Example 21 includes the subject matter of Example 20, and comprising controlling the monitored temperatures to be within a target temperature range.

Example 22 includes the subject matter of any of Examples 20-21, and comprising testing the operational performance of the DUT.

Example 23 includes the subject matter of any of Examples 20-22, and wherein controlling a cooling rate of each of the plurality of nozzles includes controlling their fluid flow rates.

Example 24 includes the subject matter of any of Examples 20-23, and wherein monitoring the temperatures includes reading temperature data from a test connector connected with the DUT.

Example 25 includes the subject matter of any of Examples 20-24, and wherein the fluid is projected upward, against gravity, onto the DUT.

Example 26 includes the subject matter of any of Examples 20-25, and wherein the projected fluid is heated to within 3 degrees C. of its boiling point.

Example 27 includes the subject matter of any of Examples 20-26, and wherein the fluid is projected onto the DUT in a vacuum chamber, and the boiling point is lower than a boiling point for the fluid at an atmospheric pressure.

Example 28 includes the subject matter of any of Examples 20-27, and wherein projecting fluid includes causing it to flow through a nozzle structure having spiral grooves to rotate the fluid before exiting the nozzle.

Example 29 includes the subject matter of any of Examples 20-28, and including controlling the nozzles with piezoelectric actuator valves.

Example 30 is a memory storage device having instructions that when executed perform the method of any of examples 20-29.

Example 31 is a test system that has a test controller coupled to a memory in accordance with the memory of example 30.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, it may be implemented on a single die, multiple dies (dielets, chiplets), one or more dies in a common package, or one or more dies in multiple packages. Along these lines, some of these blocks may be located separately on different dies or together on two or more different dies.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context. As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a group of fluid delivery nozzles each positioned to project a field of spray onto an associated zone of a device under test (DUT), wherein each zone has an associated DUT temperature; and
a test controller coupled to the nozzles to individually control each nozzle based on the associated temperature of its associated zone.

2. The apparatus of claim 1, wherein the nozzles are hollow cone nozzles.

3. The apparatus of claim 1, comprising a fluid supply source capable of providing heated and pressurized fluid.

4. The apparatus of claim 1, wherein the test controller comprises a processor circuit and executable code that when executed causes the processor circuit to increase a flow rate for a nozzle when its associated zone has an associated DUT temperature that is higher than an upper target threshold and causes the flow rate to decrease if the associated DUT temperature is below a lower target threshold.

5. The apparatus of claim 1, wherein the group of fluid delivery nozzles are positioned to project the spray upward against a net gravitational force.

6. The apparatus of claim 5, comprising a chamber having a downward sloping lower surface to channel fluid into an exhaust port.

7. The apparatus of claim 6, wherein the chamber has an additional exhaust port for maintaining a desired vacuum pressure in the chamber.

8. The apparatus of claim 1, comprising a test connector coupled with the test controller to provide it with the associated zone temperatures for the DUT.

9. A testing apparatus, comprising:
a housing having a chamber and a fluid delivery assembly with a plurality of fluid delivery nozzles to control a temperature of a device under test (DUT) having multiple zones each with an associated temperature;
a fluid input port to supply water to the plurality of fluid delivery nozzles; and
a test connector to receive the DUT and to provide the associated zone temperatures to a test controller, wherein each of the plurality of fluid delivery nozzles are individually controllable based on associated multiple zone temperatures.

10. The apparatus of claim 9, wherein the plurality of nozzles are arranged in a shape corresponding to the DUT.

11. The apparatus of claim 9, comprising a fluid supply source coupled to the fluid inlet port and capable of providing heated and pressurized fluid.

12. The apparatus of claim 9, comprising the test controller including a processor circuit and executable code that when executed causes the processor circuit to increase a flow rate for a selected one of the plurality of nozzles when an associated zone temperature is higher than an upper target threshold and causes the flow rate to decrease if the associated zone temperature is below a lower target threshold.

13. The apparatus of claim 9, wherein the plurality of fluid delivery nozzles are positioned to project the spray upward against a net gravitational force.

14. The apparatus of claim 13, comprising a chamber having a downward sloping lower surface to channel fluid into an exhaust port.

15. A method, comprising:
monitoring a temperature in each of multiple zones of a device under test (DUT);
using a plurality of nozzles to project fluid onto the DUT to control the monitored temperatures; and
controlling a cooling rate of each of the plurality of nozzles based on the monitored temperatures.

16. The method of claim 15, comprising testing the operational performance of the DUT.

17. The method of claim 15, wherein controlling a cooling rate of each of the plurality of nozzles includes controlling their fluid flow rates.

18. The method of claim 15, wherein the fluid is projected upward, against gravity, onto the DUT.

19. The method of claim 15, wherein the projected fluid is heated to within 3 degrees C. either way of its boiling point.

20. A memory storage device having instructions that when executed perform the method of claim 15.
